(19) United States
(12) Patent Application Publication
(10) Pub. No.: US 2010/0040830 A1
(43) Pub. Date: Feb. 18, 2010

(54) Droplet Deposition Component

(75) Inventor: Juergen Bruenahl, Cambridge (GB)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: XAAR TECHNOLOGY LIMITED, Cambridgeshire, Cambridge (GB)

(21) Appl. No.: 12/297,178

(22) PCT Filed: Apr. 27, 2007
(86) PCT No.: PCT/GB2007/001567

§ 371 Date: Sep. 22, 2009

(30) Foreign Application Priority Data
Apr. 28, 2006 (GB) 0608526.0

(51) Int. Cl. B32B 3/10; G03F 7/00; B29C 35/08; C23F 1/00

(52) U.S. Cl. 428/131; 430/320; 264/400; 216/27

(57) ABSTRACT

A method of forming a nozzle plate component for a printhead comprising the steps of: providing a laminar body having a polymeric upper layer defining a top surface and a metal lower layer defining a bottom surface; removing material by ablation or photolithography from the polymeric layer to selectively expose the metal layer; and applying etchant from the top surface that selectively etches the exposed areas of the metal layer, thereby undercutting said upper layer to form a recess area in the metal layer and forming an opening through said body.

The present invention relates to a component for a droplet deposition apparatus, and more particularly a nozzle plate for a droplet deposition apparatus. The present invention finds particular application in the field of drop on demand ink jet printing.

It is known to provide a composite nozzle plate, that is to say a nozzle plate formed of more than one material. WO 02/98666 for example describes a nozzle plate having a body containing a series of apertures, the apertures filled with a polymer through which nozzles are formed.

WO 05/14292 describes an alternative type of manufacture for a nozzle plate of the kind described in WO 02/98666, whereby an array of distinct polymeric bodies are formed first, around which a metallic plate is formed. Nozzles are then formed through the polymeric bodies.

These prior art constructions are complex to manufacture, requiring a large number of steps. Such constructions can also suffer the problem of poor bonding between the plate and the polymeric insert.

It is an object of the present invention to provide an improved nozzle plate component and method of manufacture.

According to a first aspect of the invention there is provided a method of forming a nozzle plate component for a droplet deposition apparatus comprising providing a body having a polymeric upper layer defining a top surface, and a metal lower layer defining a bottom surface; selectively removing material from said upper layer to selectively expose said lower layer; and processing from said top surface exposed areas of said lower layer to selectively remove material from said lower layer, thereby forming an opening through said body.

By initially providing a laminated body, it is possible to provide a very strong bond between the metal and polymer layers.

Material can be removed from the upper layer to form an essentially completed nozzle, or to form a pilot hole, to be finished into a nozzle with a subsequent processing step. By removing material from said lower layer by processing from the top surface, features in the lower layer are spatially defined by the form of the processed upper layer. Thus although the two layers are processed in separate stages, registration between the layers is easily achieved.

In one embodiment the polymer is SU-8 photoresist and the metal is nickel.

SU-8 is a photoresist developed by IBM, and described in U.S. Pat. No. 4,882,245. The main advantages of SU-8 are that it is:

photoimageable

chemically inert and temperature stable

laser ablateable at increased rate

widely used in MEMS production

transparent

The main manufacturing process for SU-8 sheets is spin coating. Film thicknesses ranging from 1 micron to 1 mm are readily achievable.

Although plain SU-8 is transparent and brittle, which makes it difficult to handle, according to the present invention it is utilised in combination with a nickel layer, thus a flexible and non-transparent laminate suitable for nozzle plate manufacture is provided. The nozzle of the completed nozzle plate is recessed into an opening in the nickel film, the nickel acting as a protective layer to make the nozzle plate scratch resistant.

According to a second aspect of the invention there is provided a nozzle plate component for a droplet deposition apparatus comprising a body having a polymeric upper layer defining a top surface, and a metal lower layer defining a bottom surface; a nozzle formed in said upper layer having an inlet in said top surface and an outlet intermediate said top and bottom surfaces, and a recess formed in said bottom layer extending around said nozzle outlet.

Preferably the component is formed by processing a blank having a polymeric upper layer and a metal lower layer.

According to a third aspect of the invention there is provided a method of forming a nozzle plate component for a droplet deposition apparatus, the nozzle plate component comprising at least one nozzle formed in a first layer of the nozzle plate component and, in axial registration with each nozzle, a respective opening formed in a second layer of the nozzle plate component, which opening is at the abutting surfaces of the first and second layers of greater radial extent than the nozzle, the method comprising the steps of:
providing a nozzle plate laminate having a first layer and a second layer;
forming an aperture in the first layer in a first forming process; and
forming an opening in the second layer in a second forming process, different from the first forming process, the location of the opening in the second forming process being determined by the location of the aperture in the first layer;
the aperture in the first layer with optional further processing serving as the nozzle.

The invention will now be described by way of an example with reference to the accompanying drawings in which:

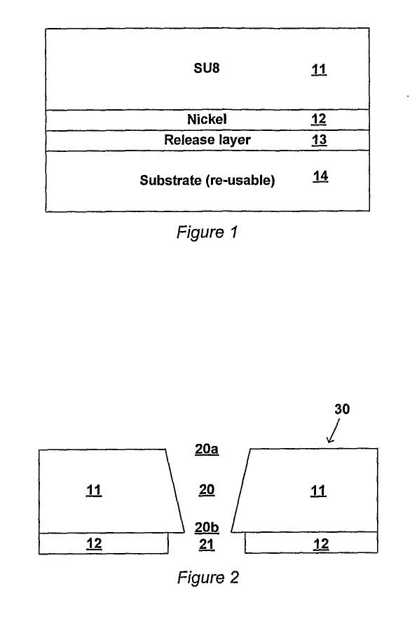

FIG. 1 illustrates a composite body or blank

FIG. 2 shows a desired nozzle shape configuration according to an aspect of the present invention.

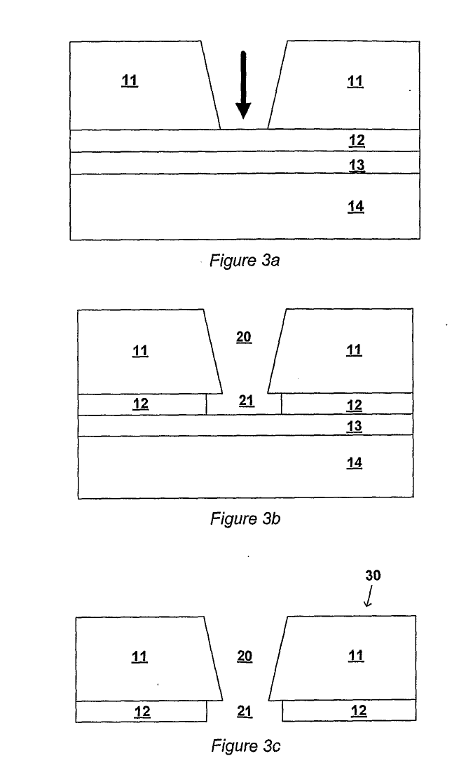

FIG. 3 illustrates a manufacturing process according to an aspect of the present invention

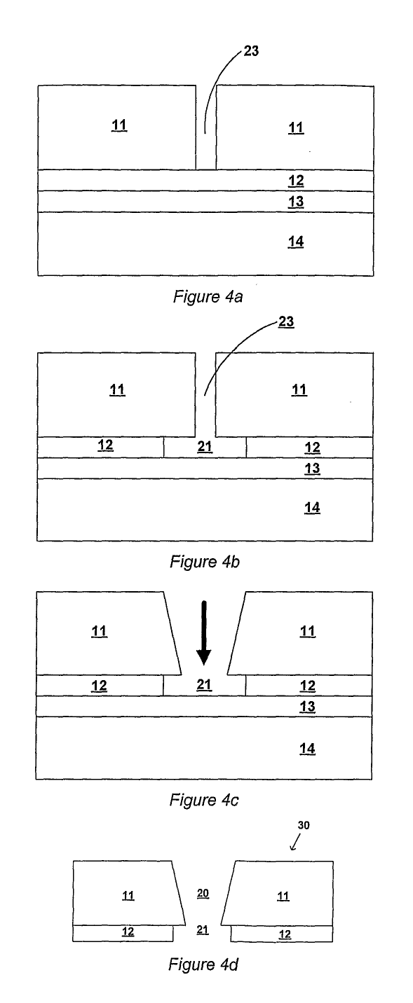

FIG. 4 illustrates an alternative manufacturing process according to an aspect of the present invention

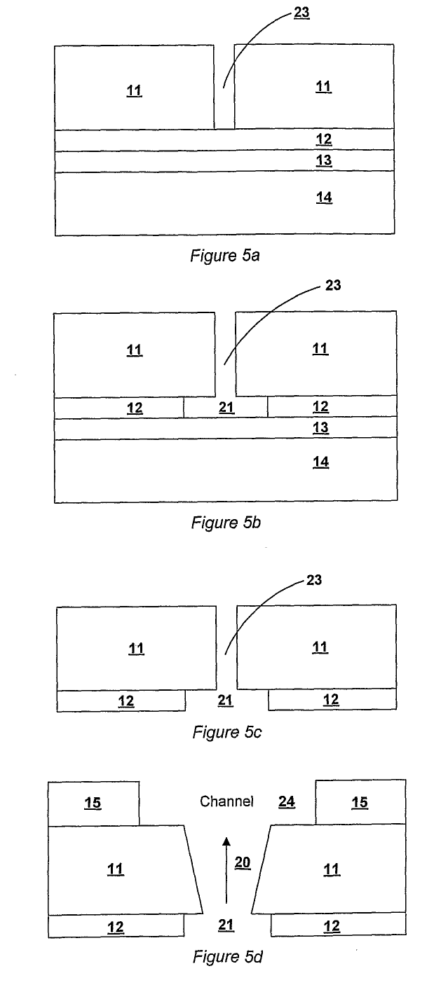

FIG. 5 illustrates a variation of the process of FIG. 4

FIG. 1 illustrates a composite body formed of a plurality of layers. A release layer 13 is built-up on a re-usable substrate 14, facilitating removal of the processed nozzle plate, followed by the lower layer 12 of the nozzle plate—here a nickel layer—and finally the upper layer of the nozzle plate 11 on top—here a layer of SU8 or polymer.

A number of examples of process steps will now be described which result in the desired nozzle plate construction as shown in FIG. 2. As displayed here, the nozzle plate component has a nozzle bore 20 extending through the upper layer 11, which tapers in diameter from the nozzle inlet 20a to the nozzle outlet 20b. There is a recess area 21 formed in the lower layer 12, which as mentioned above, protects the upper layer 11 from mechanical abrasion.

In FIG. 3a, the upper layer 11 is of photoresist and undergoes a photolithographic exposure and development process to produce a nozzle bore 20. A variety of suitable photolithographic processes are known in the art, ‘Fabrication of 3D Microstructures with Inclined/Rotated UV Lithography’ (Micro Electro Mechanical Systems, Kyoto 2003, pages 554-557) describes the creation in SU-8 of several appropriate nozzle structures including truncated cones. ‘Microfabrication of 3D Multidirectional Inclined Structures by UV Lithography and Electroplating’ (Micro Electro Mechanical Systems 1994 Proceedings, pages 81-85, IEEE Workshop) describes a further method of creating structures in positive photoresist. These or other processes can readily provide a nozzle bore having a tapered profile with a taper angle from 0 to approximately 15 degrees. Depending on the photolithographic method used, the upper layer of photoresist 11 may then undergo a post exposure bake. Suitable photolithographic processes can advantageously be used to form a large number of nozzles simultaneously.

An etching process is then applied to the body from the top surface, as shown in FIG. 3b. This locally removes part of the nickel layer 12 around the nozzle outlet to form a recess area 21. As shown, the nickel layer 12 is undercut by the etching procedure such that the nickel layer does not affect droplets ejected from the nozzle outlet 20b. An isotropic etchant may advantageously be employed here to ensure the formation of the undercut. The etchant should be selective for the nickel layer 12 over the polymer layer 11.

As shown in FIG. 3c, the finished nozzle plate component 30 is released from the substrate 14, and can be hard baked if desired.

In a process similar to that of FIG. 3, a laser can be used to process the upper layer 11 rather than a photolithographic process.

In such a process nozzle bores 20 are formed by ex-situ laser ablation, where ablation is carried out on the nozzle plate component 30 before attachment to the printhead. During this process the nickel layer 12 acts as a stop as its ablation rate is far lower than the upper layer 11, which is typically polymeric. Again, the lower layer 12 is etched through the completed nozzle bore 20 to form the recess 21, and the finished nozzle plate component 30 released from the substrate 14.

FIG. 4 illustrates a method which allows nozzle bores 20 to be formed in the upper layer 11 by laser ablation, subsequent to etching the lower layer 12.

In FIG. 4a, a small opening or pilot hole 23 is formed into the polymer layer by means of photolithography. The diameter of the openings 23 is smaller than the nozzles 20 formed by the subsequent laser ablation step.

FIG. 4b illustrates etching of the metal layer through the pilot hole, to form a recess where the nozzle outlet is to be formed. The nozzle is then formed by laser ablation from the top surface, as shown in FIG. 4c. In this way, the lip of the nozzle outlet 20b is formed free from any contact with the nickel layer 12, but with the substrate 14 providing support to maintain a flat surface.

FIG. 4d shows the finished nozzle plate component 30 separated from the substrate 14.

FIG. 5 illustrates a variation of the embodiment of FIG. 4 in which the nozzles are defined by in-situ ablation—ablation following attachment of the nozzle plate to the printhead.

FIGS. 5a and 5b illustrate formation of a small pilot hole 23 and subsequent metal etching as shown in FIGS. 4a and 4b.

At this stage the nozzle plate is released from the substrate 14 as shown in FIG. 5c, and is attached to the printhead, as shown in FIG. 5d by attachment to PZT walls 15. The assembled structure can advantageously be coated with Parylene at this stage, which serves the dual function of passivating the channel interior 24, and providing a protective coating on the outer surface of the nozzle plate in preparation for ablation. The nozzle bores 20 are then formed by laser ablation from the bottom side of the body.

It will be understood that this invention has been described by way of example only and that a wide variety of modifications are possible without departing from the scope of the invention. For example, the etching process may utilise a liquid or plasma-phase etchant, of which many types are known. Further, a wide variety of suitable materials will be apparent to those skilled in the art. The upper layer may comprise a variety of polymers susceptible to photolithography or ablation, whilst the lower layer may comprise a variety of etchable or fluid processable materials including other metals, and substrate materials used in flexible circuit board manufacture.

1. A method of forming a nozzle plate component for a droplet deposition apparatus comprising:
providing a body having a polymeric upper layer defining a top surface, and a lower layer defining a bottom surface;
removing material from said upper layer to selectively expose said lower layer in a first process; and
processing from said top surface exposed areas of said lower layer to selectively remove material from said lower layer in a second process, thereby forming an opening through said body.

2. A method according to claim 1 wherein said second process operates selectively upon said lower layer.

3. A method according to claim 1 wherein said second process undercuts said polymeric layer.

4. A method according to claim 1 wherein said first process operates selectively upon said polymeric layer.

5. A method according to claim 1, wherein said second process comprises introducing a fluid through apertures in said upper layer created by said first process.

6. A method according to claim 1, wherein selectively removing material from said upper layer comprises forming a nozzle in said upper layer.

7. A method according to claim 1, wherein selectively removing material from said upper layer results in a pilot hole in said upper layer, and subsequently comprising forming a nozzle in said upper layer around said pilot hole.

8. A method according to claim 7, comprising forming said nozzle by processing from said top surface.

9. A method according to claim 7, comprising said nozzle by processing from said bottom surface.

10. A method according to claim 6, comprising forming the inlet of said nozzle in said top surface.

11. A method according to claim 1, wherein selectively removing material from said lower layer results in a recess in said body at said nozzle outlet.

12. A method according to claim 11, wherein the recessed area is greater than the area of the outlet of said nozzle.

13. A method according to claim 1, wherein said body is releasably attached to a base layer

14. A method according to claim 1, wherein said upper layer is SU-8

15. A method according to claim 1, wherein said lower layer is a metal.

16. A method according to claim 1, wherein said lower layer is nickel.

17. A method according to claim 1, comprising selectively removing material from said upper layer by photolithographic processing.

18. A method according to claim 17, wherein said photolithographic processing results in a tapered aperture in said upper layer.

19. A method according to claim 1, comprising selectively removing material from said upper layer by laser ablation.

20. A method according to claim 1, wherein processing said lower layer to remove material comprises etching.

21. A nozzle plate component for a droplet deposition apparatus comprising
a body having a polymeric upper layer defining a top surface, and a metal lower layer defining a bottom surface;
a nozzle formed in said upper layer having an inlet in said top surface and an outlet intermediate said top and bottom surfaces; and
a recess formed in said bottom layer extending around said nozzle outlet.

22. A nozzle plate component according to claim 21, wherein said component is formed by processing a blank having a polymeric upper layer and a metal lower layer.

23. A method of forming a nozzle plate component for a droplet deposition apparatus, the nozzle plate component comprising at least one nozzle formed in a first layer of the nozzle plate component and, in axial registration with each nozzle, a respective opening formed in a second layer of the nozzle plate component, which opening is at the abutting surfaces of the first and second layers of greater radial extent than the nozzle, the method comprising:
providing a nozzle plate laminate having a first layer and a second layer;
forming an aperture in the first layer in a first forming process; and
forming an opening in the second layer in a second forming process, different from the first forming process, the location of the opening in the second forming process being determined by the location of the aperture in the first layer;
the aperture in the first layer with optional further processing serving as the nozzle.

24. A method according to claim 23, wherein the second forming process comprising passing a material removal agent throughout the aperture.

25. A method according to claim 23, wherein the material removal agent is an etchant for the material of the second layer.

26. A method according to claim 23, wherein the first forming process comprises laser ablation.

27. A method according to claim 23, wherein the first layer is formed of polymeric material and the second layer is formed of metal.

28. A method according to claim 23, wherein the formed nozzle tapers in radial extent in the axial direction toward the second layer.
